(19) United States
(12) Patent Application Publication
(10) Pub. No.: US 2024/0413043 A1
(43) Pub. Date: Dec. 12, 2024

(54) SYSTEMS, APPARATUSES, AND METHODS FOR NANOWIRES FOR SEMICONDCUTOR PACKAGES

(71) Applicant: STMicroelectronics International N.V., Geneva (CH)

(72) Inventors: Romain COFFY, Voiron (FR); Laurent Schwartz, La Buisse (FR); Ludovic Fourneaud, Saint Vincent de Mercuze (FR)

(21) Appl. No.: 18/207,918

(22) Filed: Jun. 9, 2023

(51) Int. Cl. H01L 23/373; H01L 21/48; H01L 23/367

(52) U.S. Cl. CPC H01L 23/3733; H01L 21/4882; H01L 23/3675

(57) ABSTRACT

Systems, apparatuses, and method for nanowires for semiconductor packages are provided herein. The semiconductor package may include die attached to a substrate. A lid may also be attached to the substrate. The die includes die nanowires and the lid includes lid nanowires. The nanowires may be formed over the entirety of the die or in a pattern. The lid may have a corresponding or symmetrical coverage or pattern. In the semiconductor package, the die nanowires and the lid nanowires are coupled to, among other things, provide improved heat dissipation.

### TECHNOLOGICAL FIELD

Example embodiments of the present disclosure relate generally to nanowires for semiconductor, and more particularly to heat dissipation in semiconductor packages using nanowires.

### BACKGROUND

Semiconductor packages may include a die or chip enclosed under a lid or cap. The lid acts as a heat sink to dissipate heat. A thermal interface material (TIM) may be used between the die and the lid to assist with dissipating heat from the die to the lid. TIM may degrade over time, including receding from edges of coverage where the TIM was applied between the die and the lid. Such receding decreases efficiency in dissipating heat. Also, receding in the coverage of the TIM further concentrates heat at the locations still covered by TIM drawing heat unevenly compared to uncovered locations, which may further concentrate heat and accelerate degradation.

New systems, apparatuses, and methods for semiconductor packages are needed. The inventors have identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

Various embodiments described herein relate to systems, apparatuses, and methods for nanowires for semiconductor packages.

In accordance with some embodiments of the present disclosure, an example semiconductor package is provided. The semiconductor package may comprise: a substrate; a die including a first side of the die and a second side of the die, wherein the first side of the die includes a plurality of formations of die nanowires, wherein the second side of the die is coupled to the substrate; a lid including a first side of the lid facing the die, wherein the first side of the lid includes a plurality of formations of lid nanowires; and wherein at least one formation of die nanowires is coupled to at least one formation of lid nanowires.

In some embodiments, the lid is comprised of a lid top portion and a plurality of lid side portions, and the lid top portion is coupled to the lid side portions with a glue.

In some embodiments, the least one of the plurality of formations of die nanowires is coupled to at least one of the plurality of formations of lid nanowires, and wherein the coupling is aligned with a shared a common axis.

In some embodiments, at least one of the plurality of formations of die nanowires is coupled to at least one of the plurality of formations of lid nanowires, and wherein the coupling is misaligned with the at least one of the plurality of formations of die nanowires having a different axis than the at least one of the plurality of formations of lid nanowires.

In some embodiments, the plurality of formations of lid nanowires covers a first portion of the first side of the lid that is not an entirety of the of the first side of the lid.

In some embodiments, the plurality of formations of die nanowires covers a first portion of the first side of the die that is not an entirety of the first side of the die.

In some embodiments, the first portion of the first side of the die covered by the plurality of formations of die nanowires includes coverage of at least one die hot spot.

In some embodiments, the plurality of formations of die nanowires are in a first pattern, wherein the plurality of formation of lid nanowires are in a second pattern, and wherein the first pattern and second pattern are complimentary patterns.

In some embodiments, the first side of the lid covers one or more circuitries in addition to the die.

In some embodiments, the plurality of formations of lid nanowires are only on a first portion of the lid associated with the die.

In accordance with some embodiments of the present disclosure, an example method is provided. The method may be a method of manufacturing a semiconductor packaging comprising: growing a plurality of formations of die nanowires on a first side of a die; growing a plurality of formations of lid nanowires on a first side of a lid; attaching the die to a substrate; attaching the lid to the substrate including coupling the plurality of formations of die nanowires to the plurality of formations of the lid nanowires.

In some embodiments, the lid is comprised of a lid top portion and a plurality of lid side portions, and the lid top portion is coupled to the lid side portions with a glue.

In some embodiments, at least one formation of die nanowires is coupled to at least one formation of lid nanowires, and wherein the coupling is aligned with a shared a common axis.

In some embodiments, at least one formation of die nanowires is coupled to at least one formation of lid nanowires is misaligned with the at least one formation of die nanowires having an axis that is different from the at least one formation of lid nanowires.

In some embodiments, the plurality of formations of lid nanowires cover a first portion of the first side of the lid that is not an entirety of the first side of the lid.

In some embodiments, the plurality of formations of die nanowires covers a first portion of the first side of the die that is not the entirety of the first side of the die.

In some embodiments, the first portion of the first side of the die covered by the plurality of formations of die nanowires includes coverage of at least one die hot spot.

In some embodiments, the plurality of formations of die nanowires are in a first pattern, wherein the plurality of formation of lid nanowires are in a second pattern, and wherein the first pattern and the second pattern are complimentary patterns.

In some embodiments, the first side of the lid covers one or more circuitries in addition to the die.

In some embodiments, the plurality of formations of lid nanowires are only on a first portion of the lid associated with the die.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF SUMMARY OF THE DRAWINGS

Having thus described certain example embodiments of the present disclosure in general terms, reference will now be made to the accompanying drawings, which are not necessarily drawn to scale, and wherein:

FIG. 1A illustrates a cross-section view of an example block diagram of a semiconductor package with detached lid in accordance with one or more embodiments of the present disclosure;

FIG. 1B illustrates a cross-section view of an example block diagram of a semiconductor package with an attached lid in accordance with one or more embodiments of the present disclosure;

FIGS. 2A-2C illustrate cross-section views of example block diagrams of lid nanowires and die nanowires in accordance with one or more embodiments of the present disclosure;

FIGS. 3A-3D illustrate views of example block diagrams of dies and lids in accordance with one or more embodiments of the present disclosure;

FIGS. 4A, 4B illustrate cross-section views of example block diagrams of a lid with separate top and sides in accordance with one or more embodiments of the present disclosure;

FIG. 5 illustrates a flow chart of operations for manufacturing an exemplary semiconductor package in accordance with one or more embodiments of the present disclosure;

FIG. 6 illustrates a flow chart of operations for manufacturing an exemplary die in accordance with one or more embodiments of the present disclosure; and

FIG. 7 illustrates a flow chart of operations for manufacturing an exemplary lid in accordance with one or more embodiments of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

The use of the term “circuitry” as used herein with respect to components of a system or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communications circuitry, input/output circuitry, and the like. In some embodiments, other elements may provide or supplement the functionality of particular circuitry.

### Overview

The present disclosure is directed to systems, apparatuses, and methods for semiconductor packages using nanowires for improved thermal management. Heat generated by the die during thermal cycling may lead to degradation or failure of the semiconductor package or components and/or circuitry in the semiconductor package. Dissipating heat from the semiconductor package improves semiconductor package performance and life.

The semiconductor package may include a die coupled to a substrate and a lid coupled to the substrate that covers the die and other components and/or circuitries of the semiconductor package. Nanowires may be formed each on the die and on the lid such that when the die and lid are each respectively coupled to the substrate then the die nanowires and the lid nanowires are coupled. The die nanowires and lid nanowires may be grown in a plurality of formations, which may be in a pattern. The respective formations of die nanowires and lid nanowires are what may be aligned and coupled. When coupled the die nanowires and lid nanowires make mechanical contact and electrical contact, which allows for them to be coupled and for improved dissipation of heat. An example of the semiconductor package is a ball grid array that may then be mounted to or used in an electronic device or another system.

The nanowires may be arranged in patterns, including a first pattern on a die and a second, complimentary pattern on a lid. An example pattern may be a ring or series of rings. Alternatively, a pattern may be based on characteristics of the die, such as a location of one or more hot spots. The location(s) of a hot spot may have nanowires associated with the hotspot that are configured to conduct heat away from the hotspot. Patterns may also have one or more portions of the pattern that does not include nanowires (e.g., spaces between formations of nanowires).

Nanowires improve reliability as well as thermal performance. In view of semiconductor packages utilizing TIM, nanowires as described herein may lead to an improvement in thermal dissipation of an amount of heat that is greater by a magnitude or more than with using TIM. Even if misaligned, the formations of nanowires provide increased thermal dissipation compared to semiconductor packages using TIM.

### Exemplary Systems and Apparatuses

Embodiments of the present disclosure herein include systems and apparatuses for nanowires for semiconductor packages described herein may be implemented in various embodiments. An exemplary embodiment includes a semiconductor package with a lid and a die, wherein lid nanowires are grown on the lid and die nanowires are grown on the die. When the lid is attached to a substrate where the die is attached, the lid nanowires and die nanowires are coupled. The coupled lid nanowires and die nanowires allow for, among other things, improved heat dissipation for the semiconductor package.

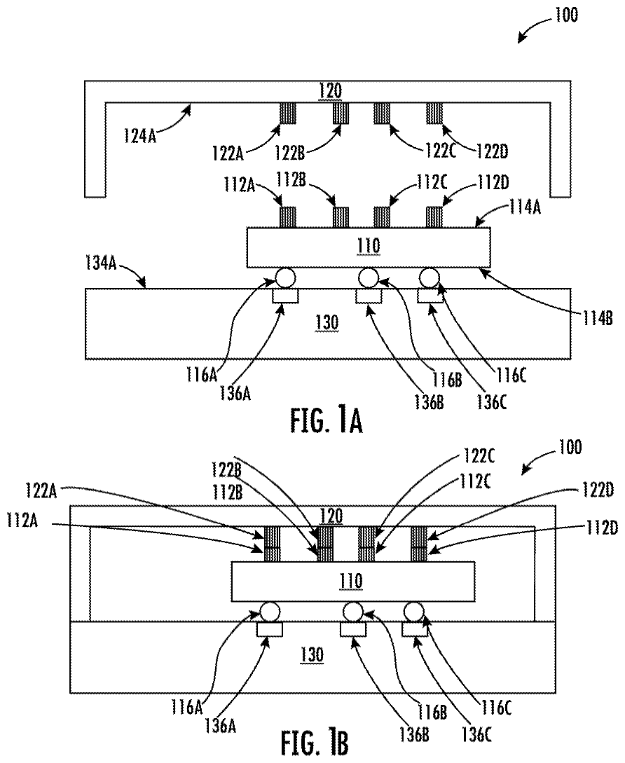

FIG. 1A illustrates a cross-section view of an example block diagram of a semiconductor package with detached lid in accordance with one or more embodiments of the present disclosure. The semiconductor package 100 may include a die 110, a lid 120, and a substrate 130. The lid 120 is illustrated detached from the substrate 130. The lid 120 detached from the substrate 130 illustrates the lid nanowires 122A-D separate from the die nanowires 112A-D.

The die 110 has a first side 114A facing the lid 120 and a second side 114B facing the substrate 130. The first side 114A of the die 110 has a plurality of formations of nanowires 112A-D. The second side 114B of the die 110 has a plurality of solder balls 116, copper pillars, or the like coupling the die 110 to the substrate 130. For example, the solder balls may be coupled to one or more signal pads 136A-C of the substrate. Nanowires on the die 110 are die nanowires. It will be appreciated that certain of the figures illustrate solder balls 116, alternative embodiments may use copper pillars or the like.

The lid 120 may include a top portion and a plurality of side portions. The top portion may have a first side 124A facing the die 110 and the substrate 120. The top portion 124A of the lid 120 may have a plurality of formations of nanowires 122A-122D. Nanowires on the lid 120 are lid nanowires. The lid may be a metallic core that is plated. For example, the lid 120 may have a copper core plate with another metal to prevent the copper from oxidizing.

A formation of nanowires (e.g., 112A-112D, 122A-122D) may include a number of nanowires grown together. While the figures may illustrate a formation of nanowires 112 as including a few nanowires, it will be appreciated that the figures are not to scale and that the number of nanowires in a formation of nanowires 112 may be based on the area of the formation of nanowires 112 on the die 110. The nanowires may be made of a metal, such as copper.

The substrate 130 may, for example, be a laminate substrate, and it may contain one or more signal pads 136 and/or other circuitries. The lid 120 may be attached to the substrate 130 to cover one or more other circuitries (e.g., ICs, electrical components, etc.) in addition the signal pads 136. The dissipation of heat generated by the die 110 with the nanowires may also provide for improved life of these other circuitries by lowering the temperatures they are exposed to. A solder mask may cover the substrate 130 and be removed in various operations, such as where and when a solder ball 116 is connected. In various embodiments, the substrate 130 may be a wafer or panel from which the semiconductor package 100 will be separated. For example, multiple semiconductor packages 100 may be manufactured together before being separated from a common wafer or panel.

FIG. 1B illustrates a cross-section view of an example block diagram of a semiconductor package with an attached lid in accordance with one or more embodiments of the present disclosure. When the lid 120 is attached to the substrate 130, the die nanowires are coupled to the lid nanowires. As illustrated, a first formation of die nanowires 112A is coupled to a first formation of lid nanowires 122A; a second formation of die nanowires 112A is coupled to a second formation of lid nanowires 122A; a third formation of die nanowires 112A is coupled to a third formation of lid nanowires 122A; a fourth formation of die nanowires 112A is coupled to a fourth formation of lid nanowires 122A. In various embodiments, when the lid 120 is attached to the substrate 130, the distance from the first side of the lid 124A to the first side of the die 114A may be 50 microns. In various embodiments, the attachment of the lid 120 to the substrate 130 may be with glue.

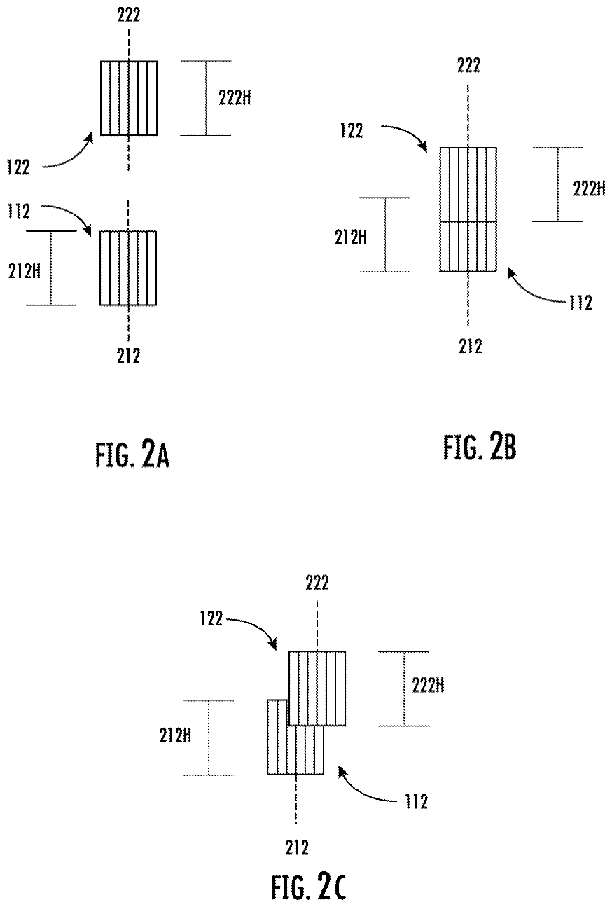

FIGS. 2A-2C illustrate cross-section views of example block diagrams of lid nanowires and die nanowires in accordance with one or more embodiments of the present disclosure. Specifically, a formation of die nanowires 112 and a formation of lid nanowires 122 are illustrated. The formation of die nanowires 112 may be of a first height 122H with a first axis of 212 and the formations of lid nanowires 122 may also be the same or a different height 222H with a second axis of 222. An axis may be referred to as a central axis. The width of a formation of nanowires (e.g., 112, 212) may be 5 to 10 microns wide, but even misaligned couplings of formations of nanowires where the axis of lid nanowires and axis of die nanowires are not aligned allow for improved thermal dissipation. A distance or gap between the die and the lid of a semiconductor package may be less than the first height 122H and the second height 222H such that when the lid 120 is attached to the substrate 130 the lid nanowires 122 will be brought into contact with the die nanowires 112 to make mechanical connections and electrical connections.

FIG. 2A illustrates a cross-section view of an example block diagram of a formation of die nanowires 112 separated from a formation of lid nanowires 122 in accordance with one or more embodiments of the present disclosure. As illustrated, while the formation of die nanowires 112 is separated from the formation of lid nanowires 122, the axes 212 and 222 have be aligned. When the formation of die nanowires 112 and the formation of lid nanowires 122 the nanowires will couple to create mechanical and electrical connections.

FIG. 2B illustrates a cross-section view of an example block diagram of a formation of die nanowires 112 coupled to a formation of lid nanowires 122 with axes 212 and 222 aligned in accordance with one or more embodiments of the present disclosure. When the axes 212 and 222 are aligned the coupling may allow for the greatest heat transfer through the coupling.

FIG. 2C illustrates a cross-section view of an example block diagram of a formation of die nanowires 112 separated from a formation of lid nanowires 122 with axes 212 and 222 not aligned in accordance with one or more embodiments of the present disclosure. When the axes 212 and 222 are not aligned but there is, as illustrated, still coupling then the heat transfer through the misaligned coupling is still improved.

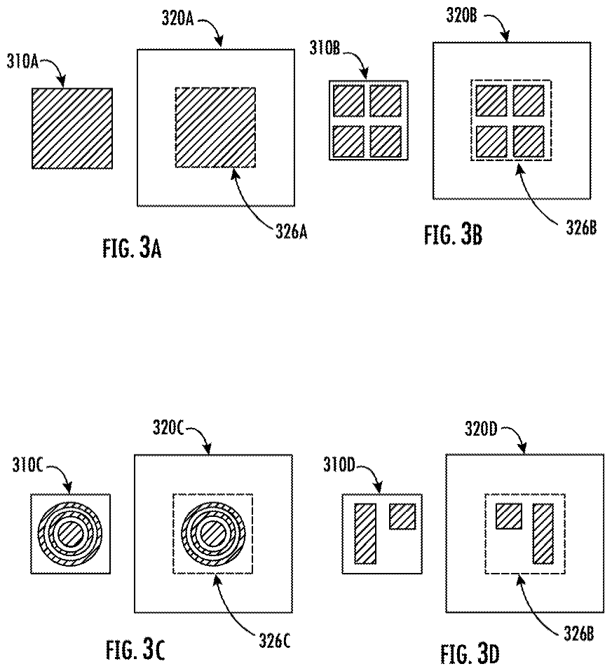

FIGS. 3A-3D illustrate views of example block diagrams of dies and lids in accordance with one or more embodiments of the present disclosure. The dies 110 and lids 120 may have patterns of nanowires. The patterns of nanowires on the lid 120 may be on a first portion of the lid 120 that is associated with the die 110. This first portion of the lid 120 may be sized based on the size of the first side 114A of the die 110. The patterns of nanowires may be made up of formations of die nanowires 112 and/or formations of lid nanowires 122. Each of FIGS. 3A-3D illustrates a die (e.g., 310A-310D) and a lid (e.g., 320A-320D). The lid (e.g., 320A-320D) is larger than the die and may include a lid portion (e.g., 326A-326D) that is size to correspond with the size of the die (e.g., 310A-310D). The die and the lid portion may be matched in size so that the die nanowires connect to the lid nanowires, including having symmetrical patterns on each. In various embodiments, patterns may have nanowires where there are one or more hotspots on the die.

FIG. 3A includes a die 310A with nanowires covering the entirety of the die 310A and it also includes a lid 320A with a first portion 326A with nanowires covering the entirety of the first portion 326A.

FIG. 3B includes a die 310B with nanowires in a pattern of four squares and it also includes a lid 320B with a first portion 326B with nanowires in a matching pattern of four squares.

FIG. 3C includes a die 310C with nanowires in a pattern of circles and it also includes a lid 320C with a first portion 326C with nanowires in a matching pattern of circles.

FIG. 3D includes a die 310D with nanowires in a pattern of a rectangle and square and it also includes a lid 320D with a first portion 326D with nanowires in a matching pattern of rectangle and a square. The patterns on the lid 310D and 320D are matched so that when the lid 320D is flipped to cover the die 310D the patterns will align.

The patterns on a die and lid may include areas and/or portions that a depopulated to not have nanowires. Such areas and/or portions may be depopulated as the die may include circuitries and/or areas or portions that do not generate as heat or as much heat to dissipate.

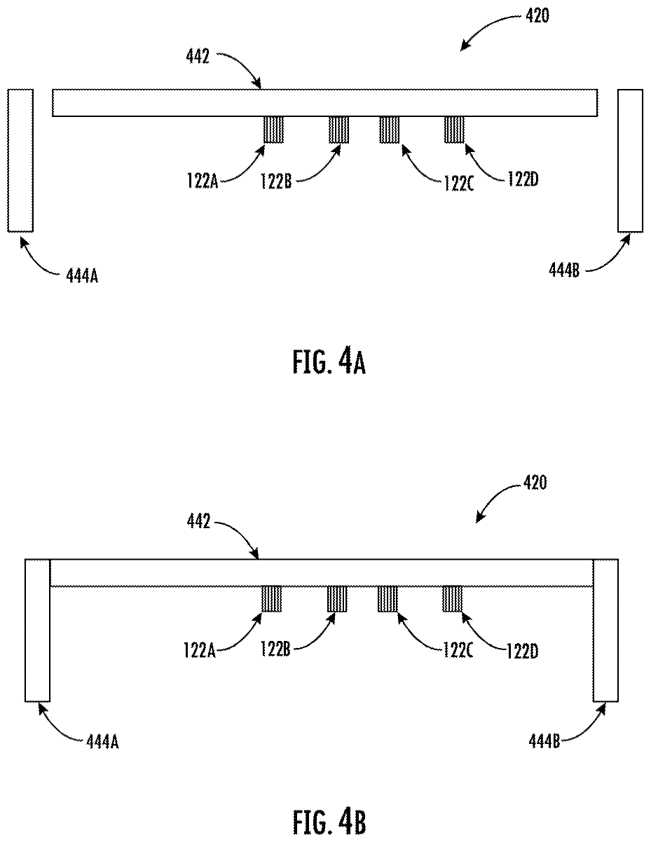

FIGS. 4A, 4B illustrate cross-section views of example block diagrams of a lid with separate top and sides in accordance with one or more embodiments of the present disclosure. In various embodiments, a lid 400 may include a top portion 442 and a plurality of side portions 444A, 444B. It will be appreciated that a lid 420 may have a side for each of its exterior sides, such as four side portions 444 for a lid 420 with a square shape. Thus the lid may be assembled from its respective portions after the nanowires have been formed on the top portion of the lid. In various embodiments, the nanowires may be formed using a deposition liquid that may be removed by centrifugal force from spinning the top portion of the lid. Thus assembling the lid in portions may allow for an easier manner of forming nanowires in various embodiments. It will be appreciate that the lid 420 may have a different shape than a square, such as a rectangle or as a shape with more or less than four sides.

FIG. 4A illustrates the lid side portions 444A, 444B detached from the top portion 442. The top portion may have formations of lid nanowires 122A-D formed on the lid top portion 442 before the lid side portions 444A, 444B are attached.

FIG. 4B illustrates the lid 420 with the lid top portion 442 attached to the side portions 444A, 444B. The attachment may be with an adhesive, such as a glue.

It should be readily appreciated that the embodiments of the systems and apparatuses, described herein may be configured in various additional and alternative manners in addition to those expressly described herein.

### Exemplary Methods

FIG. 5 illustrates a flow chart of operations for manufacturing an exemplary semiconductor package in accordance with one or more embodiments of the present disclosure.

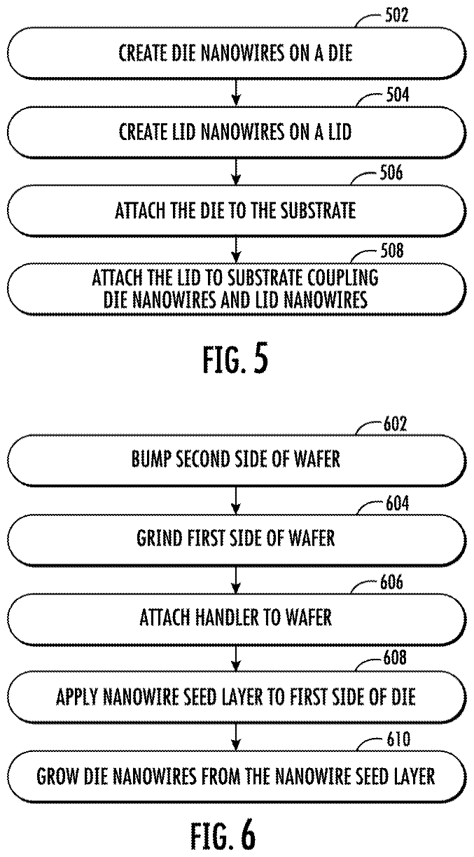

At operation 502, die nanowires are created on a die. The die nanowires 112 are created on the die 110 by plurality of operations that are described in association with FIG. 6.

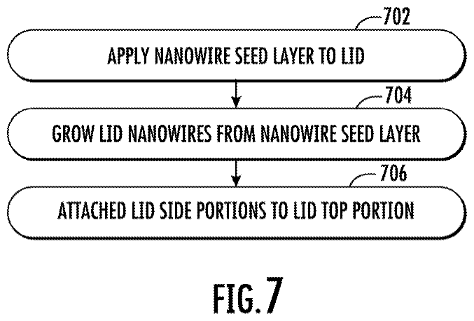

At operation 504, lid nanowire are created on a lid. The die nanowires 112 are created on the die 110 by plurality of operations that are described in association with FIG. 7.

At operation 506, the die is attached to the substrate. Attaching the die 110 to the substrate 130 may include placing the die 110 in alignment with the substrate 130 so that the solder balls 116 on the second side 114B of the die 110 are aligned with the signal pads 136 on the first side 134A of the substrate 134. If the substrate 130 included a solder mask over signal pads 134, such as to prevent oxidation of a metal of the signal pads 134, the solder mask may be removed to allow the solder balls 116 to couple to the signal pads 134. Once placed, the die 110 and the substrate 130 may be coupled by melting the solder. An underfill material may applied to fill the space around the solder and between the die 110 and the solder 130. For example, an underfill may be an epoxy that fills the space between the die 110 and the substrate 130 by capillary action.

In various embodiments, placing the die 110 may include flipping the die 110 so that the second side 114B of the die 110 is facing the first side of the substrate 130. This may include picking up the die 110 with a flip-chip holder. To use a flip-chip holder may require the die 110 be sufficiently rigid so as not to break due to the thickness of the die 110. In various embodiments, the formations of the die nanowires 112 may provide increased rigidity. This may include a pattern of die nanowires 112 that covers the entirety or the majority of the die 110.

At operation 508, the lid is attached to the substrate coupling the die nanowires and the lid nanowires. Attaching the lid to the substrate includes aligning the formations of lid nanowires with their counterparts of formations of die nanowires. This may include aligning complimentary and/or symmetrical patters of nanowires on the die 110 and lid 120. The lid 120 may be placed onto the substrate 130 and the formations of lid nanowires are brought to the formations of die nanowires. The lid 120 may be attached to the substrate 130 with a glue. In various embodiments, the attachment by glue may include depositing a glue around the substrate 130 where the side portions of the lid 120 contact the substrate 130. The semiconductor package may then be heated to, for example, 150-200 C to cure the glue. Additionally, pressure may be applied to semiconductor package or portion of the semiconductor package with the nanowires to anneal the die nanowires and lid nanowires together. The curing of the glue and the anneal may occur at the same time or may occur at separate times, such as sequentially.

FIG. 6 illustrates a flow chart of operations for manufacturing an exemplary die in accordance with one or more embodiments of the present disclosure. Creating die nanowires 112 on a die 110 may include preparing a die 110 from a plurality of dies on a wafer, on a panel, or the like. For example, the wafer may be bumped to add solder bumps and may be ground to a desired thickness. This wafer may need a handler to be attached after grinding to allow for handling of the wafer. For example, the solder bumps are on a second side 114B of the die and the die nanowires 112 will be grown on the first side 114A of the die 110, so the wafer is handled by at least flipping the wafer to expose the first side 114A of the die 110 for formations of die nanowires 112 to be grown.

At operation 602, the second side for a wafer is bumped. Multiple die may be prepared together on a wafer, including the die 110. Bumping the bottom side of the wafer, which includes the second side 114B, with solder bumps creates the solder balls 116A.

At operation 604, the first side of the wafer is grinded. The wafer may be of a standard size that may need to be reduced in thickness for the semiconductor package. The wafer, including the die 110, may be ground to a first thickness. In various embodiments, the grinding may include flipping the wafer and performing a top-side grind to remove a portion of the wafer.

At operation 606, a handler is attached to the wafer. The wafer, including die 110, may require increased rigidity for handling after being ground to a reduced thickness. A front side handler may be applied to the side of the wafer that was bumped. The front side handler may be a first material (e.g., glue or tape with glue that is thermally deactivated) that may add rigidity while absorbing the topology of the solder bumps. The handler may be a temporary layer that may later be removed. Additionally or alternatively, sawing tape may be added to the wafer to be used in a later singulation step that involves sawing the individual die from the wafer. If a handler of a first material was added, then may de-bond the handler to add the sawing tape to one or more portions of the wafer.

At operation 608, a nanowire seed layer is applied to the first side of the die. Applying a nanowire seed layer to the top of the wafer, including the first side 114A of the die 110, may be over the entirety of the die 110 or may be in one or more patterns. This may create a pattern, such as to grow nanowires on hot spots or on areas targeted for thermal dissipation. In various embodiments, the die 110 is a part of a wafer and nanowire seed layers may be applied at the same time.

At operation 610, die nanowires are grown from the nanowire seed layer. The die nanowires 112 on the first side 114A of the die 110 are grown from the nanowire seed layer. The growing of nanowires may include one or more electroplating operations. The growing of nanowires may also include applying a photoresist layer. The photoresist layer may have one or more openings or one or more openings may be created in a photoresist layer after it is applied. Nanowires may be grown in the openings of the photoresist. These openings may be formed into one or more patterns, which may allow the nanowires to be grown in one or more patterns. In various embodiments, the die 110 is a part of a wafer and multiple dies having nanowires may be grown at the same time.

In embodiments where multiple dies are a part of a wafer, the die 110 may be separated from the wafer by one or more singulation operations. This may include using a saw to saw the wafer along sawing tape applied to the wafer.

FIG. 7 illustrates a flow chart of operations for manufacturing an exemplary lid in accordance with one or more embodiments of the present disclosure. Creating lid nanowires 122 on a lid 120 may include applying a nanowire seed layer to the lid 120 and growing the lid nanowires 122 from the seed layer. In various embodiments where the lid 420 includes a top portion 442 detached from side portions 444, one or more lid top portion(s) 442 may be prepared by growing lid nanowires 122 on the top portion(s) 442 before the respective side portions 444 are attached to the top portion(s) 442. Then, after lid nanowires 122 have grown on the top portion(s) 442, the respective lid side portions 444 are attached to the lid top portion(s) 442.

At operation 702, a nanowire seed layer is applied to the lid. A lid 120 may include a applying the nanowire seed layer may include covering all of an area of the lid in a pattern or, after the seed layer is applied, removing one or more portions of the seed layer. In various embodiments, the patterns may have the seed layer applied in one or more shapes. In various embodiments, the patterns may have the seed layer applied only to hot spots.

At operation 704, lid nanowires are grown from the nanowire seed layer. Generating nanowires on nanowire seed layer, which may include electroplating. The growing of nanowires may also include applying a photoresist layer. The photoresist layer may have one or more openings or one or more openings may be created in a photoresist layer after it is applied. Nanowires may be grown in the openings of the photoresist. These openings may be formed into one or more patterns, which may allow the nanowires to be grown in one or more patterns.

At operation 706, lid side portions are attached to the lid top portion. In various embodiments where the lid comes in multiple portions, the following steps may be followed by attached one or more side portions of the lid to lid portion with the nanowires. For example, the attachment may be done with one or more glues.

### CONCLUSION

Operations and/or functions of the present disclosure have been described herein, such as in flowcharts. While operations and/or functions are illustrated in the drawings in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

While this specification contains many specific embodiment and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

While this detailed description has set forth some embodiments of the present invention, the appended claims cover other embodiments of the present invention which differ from the described embodiments according to various modifications and improvements.

Within the appended claims, unless the specific term “means for” or “step for” is used within a given claim, it is not intended that the claim be interpreted under 35 U.S.C. § 112, paragraph 6.

1. A semiconductor package comprising:
a substrate;
a die including a first side of the die and a second side of the die, wherein the first side of the die includes a plurality of formations of die nanowires, wherein the second side of the die is coupled to the substrate;
a lid including a first side of the lid facing the die, wherein the first side of the lid includes a plurality of formations of lid nanowires; and
wherein at least one formation of die nanowires is coupled to at least one formation of lid nanowires.

2. The semiconductor package of claim 1, wherein the lid is comprised of a lid top portion and a plurality of lid side portions, and the lid top portion is coupled to the lid side portions with a glue.

3. The semiconductor package of claim 1, wherein the least one of the plurality of formations of die nanowires is coupled to at least one of the plurality of formations of lid nanowires, and wherein the coupling is aligned with a shared a common axis.

4. The semiconductor package of claim 1, wherein at least one of the plurality of formations of die nanowires is coupled to at least one of the plurality of formations of lid nanowires, and wherein the coupling is misaligned with the at least one of the plurality of formations of die nanowires having a different axis than the at least one of the plurality of formations of lid nanowires.

5. The semiconductor package of claim 1, wherein the plurality of formations of lid nanowires covers a first portion of the first side of the lid that is not an entirety of the of the first side of the lid.

6. The semiconductor package of claim 1, wherein the plurality of formations of die nanowires covers a first portion of the first side of the die that is not an entirety of the first side of the die.

7. The semiconductor package of claim 6, wherein the first portion of the first side of the die covered by the plurality of formations of die nanowires includes coverage of at least one die hot spot.

8. The semiconductor package of claim 1, wherein the plurality of formations of die nanowires are in a first pattern, wherein the plurality of formation of lid nanowires are in a second pattern, and wherein the first pattern and second pattern are complimentary patterns.

9. The semiconductor package of claim 1, wherein the first side of the lid covers one or more circuitries in addition to the die.

10. The semiconductor package of claim 9, wherein the plurality of formations of lid nanowires are only on a first portion of the lid associated with the die.

11. A method of manufacturing a semiconductor package comprising:
growing a plurality of formations of die nanowires on a first side of a die;
growing a plurality of formations of lid nanowires on a first side of a lid;
attaching the die to a substrate;
attaching the lid to the substrate including coupling the plurality of formations of die nanowires to the plurality of formations of the lid nanowires.

12. A method of manufacturing a semiconductor package of claim 11, wherein the lid is comprised of a lid top portion and a plurality of lid side portions, and the lid top portion is coupled to the lid side portions with a glue.

13. A method of manufacturing a semiconductor package of claim 11, wherein at least one formation of die nanowires is coupled to at least one formation of lid nanowires, and wherein the coupling is aligned with a shared a common axis.

14. A method of manufacturing a semiconductor package of claim 11, wherein at least one formation of die nanowires is coupled to at least one formation of lid nanowires is misaligned with the at least one formation of die nanowires having an axis that is different from the at least one formation of lid nanowires.

15. A method of manufacturing a semiconductor package of claim 11, wherein the plurality of formations of lid nanowires cover a first portion of the first side of the lid that is not an entirety of the first side of the lid.

16. A method of manufacturing a semiconductor package of claim 11, wherein the plurality of formations of die nanowires covers a first portion of the first side of the die that is not the entirety of the first side of the die.

17. A method of manufacturing a semiconductor package of claim 16, wherein the first portion of the first side of the die covered by the plurality of formations of die nanowires includes coverage of at least one die hot spot.

18. A method of manufacturing a semiconductor package of claim 11, wherein the plurality of formations of die nanowires are in a first pattern, wherein the plurality of formation of lid nanowires are in a second pattern, and wherein the first pattern and the second pattern are complimentary patterns.

19. A method of manufacturing a semiconductor package of claim 11, wherein the first side of the lid covers one or more circuitries in addition to the die.

20. A method of manufacturing a semiconductor package of claim 19, wherein the plurality of formations of lid nanowires are only on a first portion of the lid associated with the die.
